(19) United States
(12) Patent Application Publication
(10) Pub. No.: US 2022/0310688 A1
(43) Pub. Date: Sep. 29, 2022

(54) IMAGE SENSING DEVICE AND MANUFACTURING METHOD THEREOF

(71) Applicant: Egis Technology Inc., Hsinchu City (TW)

(72) Inventor: Chen-Wei Fan, Hsinchu City (TW)

(73) Assignee: Egis Technology Inc., Hsinchu City (TW)

(21) Appl. No.: 17/676,864

(22) Filed: Feb. 22, 2022

Related U.S. Application Data
(60) Provisional application No. 63/166,228, filed on Mar. 25, 2021.

(30) Foreign Application Priority Data
Jan. 14, 2022 (CN) 202210043079.0

(51) Int. Cl. H01L 27/146

(52) U.S. Cl. CPC H01L 27/14621; H01L 27/14627; H01L 27/14685

(57) ABSTRACT

An image sensing device including an image sensor, a color filtering unit set, and a light deflecting unit set is provided. The image sensor has a plurality of sub-pixels arranged in an array. The color filtering unit set is disposed above the image sensor, and has a plurality of first filter units and a plurality of second filter units. A central transmitting wavelength of the first filter units is greater than a central transmitting wavelength of the second filter units. The light deflecting unit set is disposed between the color filtering unit set and the image sensor, and has a plurality of first light deflecting units. A refractive index of the first light deflecting units is greater than a refractive index of a medium between the second filter units and a plurality of corresponding sub-pixels. A manufacturing method of an image sensing device is also provided.

### CROSS-REFERENCE TO RELATED APPLICATION

This application claims the priority benefit of U.S. provisional application Ser. No. 63/166,228, filed on Mar. 25, 2021, and China application serial no. 202210043079.0, filed on Jan. 14, 2022. The entirety of each of the above-mentioned patent applications is hereby incorporated by reference herein and made a part of this specification.

### BACKGROUND OF THE INVENTION

### Field of the Invention

The invention relates to an optoelectronic device and a manufacturing method thereof, and in particular, to an image sensing device and a manufacturing method thereof.

### Description of Related Art

In the field of optoelectronic techniques, an image sensing device is an important device, which is needed for various measurements or image capture. In an image sensor capable of obtaining a color image, a color filter array and a microlens array may be provided above the image sensing unit array.

For the light incident on the image sensing unit obliquely, especially the light incident on the edge area of the image sensing device, since light of different wavelengths has different refractive indices, the microlens array focuses light of different wavelengths on different positions of the image sensing unit, thereby affecting the accuracy of sensing. To solve this issue, one method is to shift the microlenses on the filter units of different colors relative to the image sensing unit by different shift amounts, so that light of different colors may all be focused on the center of the image sensing unit.

However, when the pixel size of the image sensing device is smaller and smaller, when the fill factor of the microlenses is made larger and larger and the distance between adjacent microlenses is made smaller and smaller, when the chief ray angle is made larger and larger such that the shift amount of the microlenses relative to the image sensing unit needs to be increased, or when the sensed light includes ultraviolet light or infrared light and the shift amount of the microlenses relative to the image sensing unit needs to be increased, position overlap interference occurs to adjacent microlenses under the optimal design value. At this time, it is necessary to sacrifice the optimal shift amount design of the microlenses, thus affecting the sensing accuracy and sensing effect of the image sensing device.

### SUMMARY OF THE INVENTION

The invention provides an image sensing device having good accuracy and effect for sensing images of various colors.

The invention provides a manufacturing method of an image sensing device, wherein the manufactured image sensing device has good accuracy and effect for sensing images of various colors.

An embodiment of the invention provides an image sensing device including an image sensor, a color filtering unit set, and a light deflecting unit set. The image sensor has a plurality of sub-pixels arranged in an array. The color filtering unit set is disposed above the image sensor, and has a plurality of first filter units and a plurality of second filter units. Each of the first filter units and the second filter units respectively corresponds to one sub-pixel on an optical path, wherein a central transmitting wavelength of the first filter units is greater than a central transmitting wavelength of the second filter units. The light deflecting unit set is disposed between the color filtering unit set and the image sensor, and has a plurality of first light deflecting units. A refractive index of the first light deflecting units is greater than a refractive index of a medium between the second filter units and a plurality of corresponding sub-pixels, and the first light deflecting units respectively correspond to the first filter units on the optical path. After passing through the first filter units and the second filter units, a light from an outside is respectively deflected by the first light deflecting units and transmitted to the plurality of corresponding sub-pixels by the medium.

An embodiment of the invention provides an image sensing device including an image sensor and a color filtering unit set. The image sensor has a plurality of sub-pixels arranged in an array. The color filtering unit set is disposed above the image sensor, and has a plurality of first filter units and a plurality of second filter units. Each of the first filter units and the second filter units respectively corresponds to one sub-pixel on an optical path, wherein a central transmitting wavelength of the first filter units is greater than a central transmitting wavelength of the second filter units, and a refractive index of the first filter units is greater than a refractive index of the second filter units. After passing through the first filter units and the second filter units, a light from an outside is respectively deflected to a plurality of corresponding sub-pixels.

A manufacturing method of an image sensing device provided by an embodiment of the invention includes: providing an image sensor, wherein the image sensor has a plurality of sub-pixels arranged in an array; forming a light deflecting unit set above the image sensor, wherein the light deflecting unit set has a plurality of first light deflecting units respectively located above a portion of the sub-pixels; and forming a color filtering unit set on the light deflecting unit set, wherein the color filtering unit set has a plurality of first filter units and a plurality of second filter units. Each of the first filter units and the second filter units respectively corresponds to one sub-pixel on an optical path, wherein a central transmitting wavelength of the first filter units is greater than a central transmitting wavelength of the second filter units, and a refractive index of the first light deflecting units is greater than a refractive index of a medium between the second filter units and a plurality of corresponding sub-pixels.

An embodiment of the invention provides a manufacturing method of an image sensing device, including: providing an image sensor, wherein the image sensor has a plurality of sub-pixels arranged in an array; and forming a color filtering unit set above the image sensor. The color filtering unit set has a plurality of first filter units and a plurality of second filter units, and each of the first filter units and the second filter units respectively corresponds to one sub-pixel on an optical path. A central transmitting wavelength of the first filter units is greater than a central transmitting wavelength of the second filter units, and a refractive index of the first filter units is greater than a refractive index of the second filter units.

In the image sensing device and the manufacturing method thereof of the embodiments of the invention, since light deflecting units having different refractive indices are adopted to refract light of different wavelengths, or filter units having different refractive indices are adopted to refract light of different wavelengths, the obliquely incident light of different wavelengths may be accurately converged to the corresponding sub-pixels. Therefore, the image sensing device of an embodiment of the invention or the image sensing device manufactured by the manufacturing method of the image sensing device of an embodiment of the invention has good accuracy and effect for sensing images of various colors.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a schematic side view of an image sensing device of an embodiment of the invention.

FIG. 1B is a schematic cross-sectional view of the image sensing device of FIG. 1A in the A1 area.

FIG. 2 is a schematic cross-sectional view of the image sensing device of another embodiment of FIG. 1A in the area A1.

FIG. 3 is a flowchart of a manufacturing method of the image sensing device of FIG. 1B.

FIG. 4 is a flowchart of a manufacturing method of the image sensing device of FIG. 2.

### DESCRIPTION OF THE EMBODIMENTS

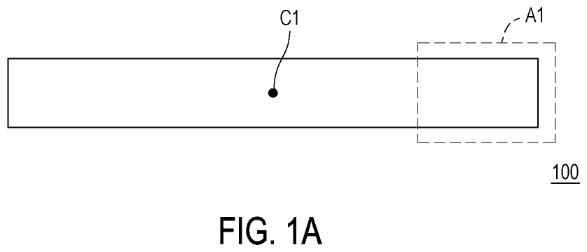

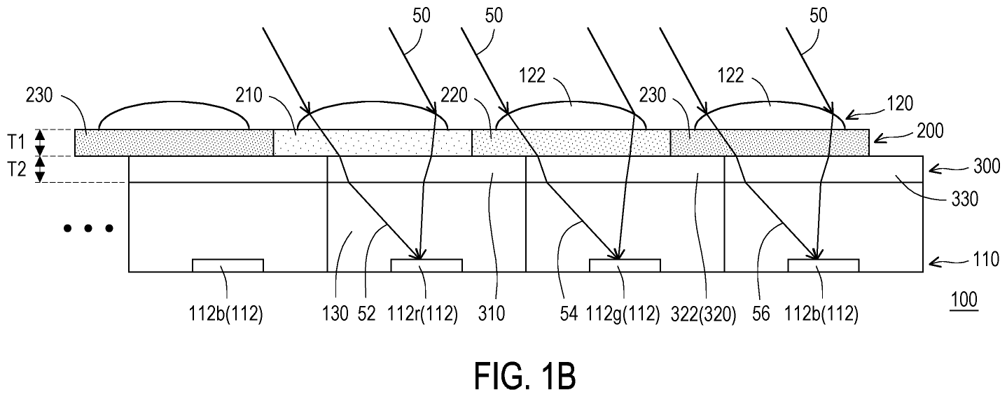

FIG. 1A is a schematic side view of an image sensing device of an embodiment of the invention, and FIG. 1B is a schematic cross-sectional view of the image sensing device of FIG. 1A in the A1 area. Referring to FIG. 1A and FIG. 1B, an image sensing device 100 of the present embodiment includes an image sensor 110, a color filtering unit set 200, and a light deflecting unit set 300. The image sensor 110 has a plurality of sub-pixels 112 arranged in an array. In the present embodiment, the image sensor 110 is, for example, a complementary metal-oxide-semiconductor (CMOS) image sensor, a charge-coupled device (CCD), or other suitable image sensors, and a photodiode may be provided in the sub-pixels 112 to sense a light 50 from the outside. The color filtering unit set 200 is disposed above the image sensor 110 and has a plurality of first filter units 210 and a plurality of second filter units 220. Each of the first filter units 210 and the second filter units 220 respectively corresponds to one sub-pixel 112 on the optical path. In the present embodiment, the color filter units include a plurality of first filter units 210 and a plurality of second filter units 220 arranged alternately, and a filter unit is provided above each of the sub-pixels 112. However, in another embodiment, a filter unit may also not be provided above most of the sub-pixels 112 or a material without filter function is provided above most of the sub-pixels 112, and one first filter unit 210 and one second filter unit 220 are adjacent to each other in an edge-to-edge or corner-to-corner manner to form one group scattered above a small portion of some of the sub-pixels 112. In an embodiment, the central transmitting wavelength of the first filter units 210 is greater than the central transmitting wavelength of the second filter units 220. The light deflecting unit set 300 is disposed between the color filtering unit set 200 and the image sensor 110, and has a plurality of first light deflecting units 310. In an embodiment, the refractive index of the first light deflecting units 310 is greater than the refractive index of a medium 322 located between the second filter units 220 and the corresponding sub-pixels, and the first light deflecting units 310 respectively correspond to the first filter units 210 on the optical path. In the present embodiment, the light deflecting unit set 300 has the first light deflecting units 310 arranged at intervals, and each of the sub-pixels 112 has a filter unit above. However, in an embodiment in which the groups of the first filter units 210 and the second filter units 220 are scattered above a small number of the sub-pixels 112, the first light deflecting units 310 may also be scattered below the first filter units 210 of these groups.

After passing through the first filter units 210 and the second filter units 220, the light 50 from the outside is respectively transmitted to the plurality of corresponding sub-pixels 112 by the first light deflecting units 310 and the medium 322. Specifically, the first filter units 210 are, for example, red filter units, the second filter units 220 are, for example, green filter units, the light 50 becomes a red light 52 after passing through the first filter units 210, and then the red light 52 is deflected by the first light deflecting units 310 to a sub-pixel 112r. Similarly, the light 50 becomes a green light 54 after passing through the second filter units 220, and then the green light 54 is transmitted to a sub-pixel 112g by the medium 322.

In another embodiment, the color filtering unit set 200 may include a plurality of third filter units 230. The first filter units 210, the second filter units 220, and the third filter units 230 respectively correspond to sub-pixels 112r, 112g, and 112b on the optical path. In the present embodiment, the first filter units 210, the second filter units 220, and the third filter units 230 are alternately arranged, and a filter unit is provided above each of the sub-pixels 112. However, in another embodiment, a filter unit may also not be provided above most of the sub-pixels 112, and one first filter unit 210, one second filter unit 220, and one third filter unit 230 are adjacent to each other in an edge-to-edge or corner-to-corner manner to form one group (e.g., straight line group, diagonal group, or V-shaped group), and a plurality of such groups are scattered over a small portion of the sub-pixels 112. In the present embodiment, the central transmitting wavelength of the second filter units 220 is greater than the central transmitting wavelength of the third filter units 230. For example, the third filter units 230 are, for example, blue filter units. In an embodiment, the light deflecting unit set 300 further includes a plurality of second light deflecting units 320 and a plurality of third light deflecting units 330 (the third light deflecting units 330 may also be replaced by another medium), wherein the medium 322 is the second light deflecting units 320. In the present embodiment, the first light deflecting units 310, the second light deflecting units 320, and the third light deflecting units 330 are alternately arranged, and a filter unit is provided above each of the sub-pixels 112. However, in an embodiment in which the groups of the first filter units 210, the second filter units 220, and the third filter units 230 are scattered over a small portion of the sub-pixels 112, the first light deflecting units 310, the second light deflecting units 320, and the third light deflecting units 330 may also be scattered below the groups of the first filter units 210, the second filter units 220, and the third filter units 230, respectively. In the present embodiment, the refractive index of the first light deflecting units 310 is greater than the refractive index of the second light deflecting units 320, the refractive index of the second light deflecting units 320 is greater than the refractive index of the third light deflecting units 330, and the first light deflecting units 310, the second light deflecting units 320, and the third light deflecting units 330 correspond to the first filter units 210, the second filter units 220, and the third filter units 230 respectively on the optical path. After the light 50 from the outside passes through the first filter units 210, the second filter units 220, and the third filter units 230, the light 50 is respectively transmitted to the corresponding sub-pixels 112r, 112g, and 112b by the first light deflecting units 310, the second light deflecting units 320, and the third light deflecting units 330.

Specifically, in the present embodiment, the light 50 becomes the green light 54 after passing through the second filter units 220, and the second light deflecting units 320 deflect the green light 54 to the sub-pixels 112g. The light 50 becomes a blue light 56 after passing through the second filter units 230, and the third light deflecting units 330 deflect the blue light 56 to the sub-pixels 112b.

In the present embodiment, the image sensing device 100 further includes a lens array 120 including a plurality of lenses 122 arranged in an array, wherein the lenses 122 are respectively disposed on the first filter units 210, the second filter units 220, and the third filter units 230. In other embodiments, in addition to being disposed on the first filter units 210, the second filter units 220, and the third filter units 230, the lenses 122 may also be disposed above some sub-pixels, and filter units may be omitted above these sub-pixels.

For the control group in which one image sensing device omits the light deflecting unit set 300, the refractive index of the lenses 122 is the smallest for the red light 52 in the light 50 from the outside, the refractive index thereof for the green light 54 is the second smallest, and the refractive index thereof for the blue light 56 is the largest. Therefore, for the light 50 obliquely incident on the lens array 120, when the light 50 passes through the first filter units 210 and becomes the red light 52, the light 50 is converged to the position towards the right of the sub-pixel 112r in the figure, when the light 50 passes through the second filter units 220 and becomes the green light 54, the light 50 is converged to the center position of the sub-pixel 112g, and when the light 50 passes through the third filter units 230 and becomes blue light 56, the light 50 is converged to the position towards the left of the sub-pixel 112b in the figure. As a result, the red light 52 and the blue light 56 cannot be well and accurately sensed, thus affecting the sensing accuracy and effect of the image sensing device.

In comparison, in the image sensing device 100 of the present application, since the light deflecting unit set 300 is adopted, the first light deflecting unit 310 having the highest refractive index is responsible for deflecting the red light 52, the second light deflecting unit 320 having the second highest refractive index is responsible for deflecting the green light 54, and the third light deflecting unit 330 having the lowest refractive index is responsible for deflecting the blue light 56, wherein here, the refractive indices of the first, second, and third light deflecting units 310, 320, and 330 compared with each other, for example, all refer to the refractive index for the green light 54 uniformly. That is, here, the light 50 is taken as an example by passing through the first filter units 210, the second filter units 220, and the third filter units 230 (i.e., the red, green, and blue filter units) to form the red light 52, the green light 54, and the blue light 56, wherein the wavelength in the middle corresponds to the green light 54, and therefore the refractive indices compared with each other above refer to the refractive index for the green light 54 uniformly. As a result, the red light 52 may be focused on the center of the sub-pixel 112r, the green light 54 may be focused on the center of the sub-pixel 112g, and the blue light 56 may be focused on the center of the sub-pixel 112b. Therefore, the image sensing device 100 of the present embodiment may have good sensing accuracy and effect.

In the present embodiment, at the position deviating from a center C1 of the image sensing device 100, the first filter units 210, the second filter units 220, and the third filter units 230 are shifted toward the center of the image sensor 110 relative to the corresponding sub-pixel 112 (that is, shifted toward the center C1). Moreover, in the present embodiment, the first light deflecting units 310, the second light deflecting units 320, and the third light deflecting units 330 are aligned with the corresponding sub-pixels 112r, 112g, and 112b (for example, the center of the first light deflecting units 310, the center of the second light deflecting units 320, and the center of the third light deflecting units 330 are aligned with the center of the corresponding sub-pixel 112r, the center of the corresponding sub-pixel 112g, and the center of the corresponding sub-pixel 112b respectively), and the first filter units 210, the second filter units 220, and the third filter units 230 are shifted toward the center of the sensor 110 relative to the corresponding first light deflecting units 310, second light deflecting units 320, and third light deflecting units 330 (i.e., shifted toward the center C1).

In the image sensing device 100 of the present application, since the light deflecting unit set 300 is adopted to deflect the red light 52, the green light 54, and the blue light 56 to different degrees, the shift degrees of three adjacent lenses 122 corresponding to the first filter units 210, the second filter units 220, and the third filter units 230 respectively relative to the corresponding sub-pixels 112r, 112g, and 112b may be the same or similar, and therefore the issue of positional interference between adjacent lenses 122 in the prior art does not occur. In addition, when the pixels of the image sensing device 100 are made smaller and smaller, when the fill factor of the lenses 122 is made larger and larger and the spacing between adjacent lenses 122 is made smaller and smaller, when the chief ray angle is made larger and larger such that the shift amount of the lenses 122 relative to the sub-pixels 112 needs to be increased, or when the sensed light 50 includes ultraviolet light or infrared light and the shift amount of the lenses 122 relative to the sub-pixels 112 needs to be increased, adjacent lenses 122 still do not have the issue of positional interfere with each other, but the shift amount of the lenses 122 may be designed at an optimal position, and the light of the target wavelength may still be correctly converged to the sub-pixels. The image sensing device 100 thus designed has lower spectral crosstalk.

In the present embodiment, the ratio of a thickness T2 of the light deflecting unit set 300 to a thickness T1 of the color filtering unit set 200 is in the range of 0.8 to 38.

In the present embodiment, the image sensing device 100 further includes a spacer device 130 disposed between the image sensor 110 and the light deflecting unit set 300, wherein the spacer device 130 may be a stacked film layer, such as a stacked transparent medium layer.

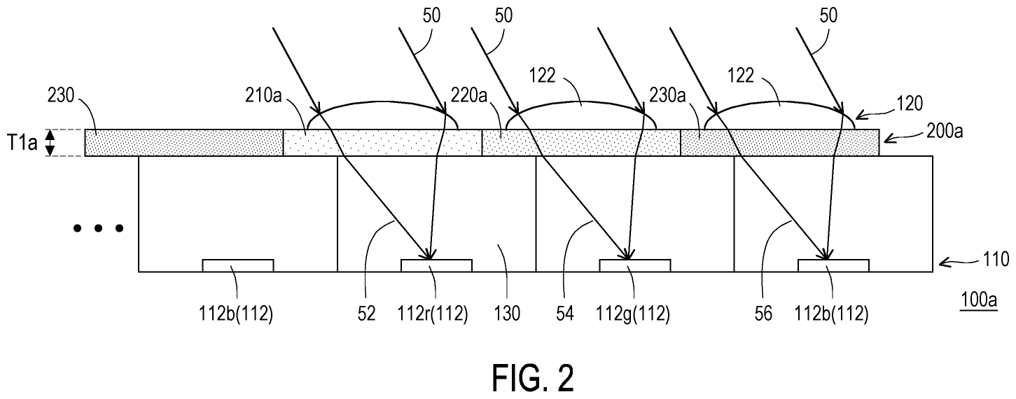

FIG. 2 is a schematic cross-sectional view of the image sensing device in the area A1 of another embodiment of FIG. 1A. Referring to FIG. 2, an image sensing device 100a of the present embodiment is similar to the image sensing device 100 of FIG. 1B, and the difference between the two is that in the image sensing device 100 of FIG. 1B, the refractive indices of the first, second, and third filter units 210, 220, and 230 are equal or substantially equal, wherein the light deflecting unit set 300 is adopted to deflect light of different colors to different degrees. In comparison, the image sensing device 100a of the embodiment shown in FIG. 2 does not adopt a light deflecting unit set. Instead, the refractive indices of first, second, and third filter units 210a, 220a, and 230a themselves are different (the refractive indices here are, for example, uniformly the refractive index for green light) to deflect light of different colors to different degrees.

Specifically, in the present embodiment, the central transmission wavelength of the first filter units 210a is greater than the central transmission wavelength of the second filter units 220a, the refractive index of the first filter units 210a is greater than the refractive index of the second filter units 220a, and after the light 50 from the outside is deflected by the first filter units 210a and the second filter units 220a, the light 50 is respectively transmitted to the plurality of corresponding sub-pixels 112r and 112g.

In the present embodiment, the central transmission wavelength of the second filter units 220a is greater than the central transmission wavelength of the third filter units 230a, the refractive index of the second filter units 220a is greater than the refractive index of the third filter units 230a, and after the light 50 from the outside is deflected by the first filter units 210a, the second filter units 220a, and the third filter units 230a, the light 50 is respectively transmitted to the corresponding sub-pixels 112r, 112g, and 112b. In the present embodiment, the first filter units 210a are, for example, red filter units, the second filter units 220a are, for example, green filter units, and the third filter units 230a are, for example, blue filter units. After the light 50 passes through the lenses 122 and the first filter units 210a in sequence, the light 50 becomes the red light 52, and the red light 52 is deflected to the sub-pixel 112r. After the light 50 passes through the lenses 122 and the second filter units 220a in sequence, the light 50 becomes the green light 54, and the green light 54 is deflected to the sub-pixel 112g. After the light 50 passes through the lenses 122 and the third filter units 230a in sequence, the light 50 becomes the blue light 56, and the blue light 56 is deflected to the sub-pixel 112b.

For a control group of the conventional image sensing device without a light deflecting unit set and for which the refractive index of each of the color filter units is substantially the same, the refractive index of the lenses 122 is the smallest for the red light 52 in the light 50 from the outside, the refractive index thereof for the green light 54 is the second smallest, and the refractive index thereof for the blue light 56 is the largest. Therefore, for the light 50 obliquely incident on the lens array 120, when the light 50 passes through the red filter units and becomes the red light 52, the light 50 is converged to the position towards the right of the sub-pixel 112r in the figure, when the light 50 passes through the green filter units and becomes the green light 54, the light 50 is converged to the center position of the sub-pixel 112g, and when the light 50 passes through the blue filter units and becomes blue light 56, the light 50 is converged to the position towards the left of the sub-pixel 112b in the figure. As a result, the red light 52 and the blue light 56 may not be well and accurately sensed, thus affecting the sensing accuracy and effect of the image sensing device.

In comparison, in the image sensing device 100a of the present embodiment, since the refractive index of the first filter units 210a is largest, the refractive index of the second filter units 220a is second largest, and the refractive index of the third filter units 230a is smallest, the first filter units 210a may deflect the red light 52 to the most extent, the second filter units 220a may deflect the green light 54 to the second most extent, and the third filter units 230a may deflect the blue light 56 to the least extent. As a result, the red light 52 may be focused on the center of the sub-pixel 112r, the green light 54 may be focused on the center of the sub-pixel 112g, and the blue light 56 may be focused on the center of the sub-pixel 112b. Therefore, the image sensing device 100 of the present embodiment may have good sensing accuracy and effect.

In the present embodiment, at a position deviated from the center of the image sensing device 100a (refer to the center C1 of the image sensing device 100 of FIG. 1A), the first filter units 210a, the second filter units 220a, and the third filter units 230a are shifted toward the center of the image sensor relative to the corresponding sub-pixels 112r, 112g, and 112b (that is, shifted toward the center C1).

In the image sensing device 100a of the present embodiment, since the first filter units 210a, the second filter units 220a, and the third filter units 230a having different refractive indices are adopted to deflect the red light 52, the green light 54, and the blue light 56 to different degrees, the shift degrees of three adjacent lenses 122 corresponding to the first filter units 210a, the second filter units 220a, and the third filter units 230a respectively relative to the corresponding sub-pixels 112r, 112g, and 112b may be the same or similar, and therefore the issue of positional interference between adjacent lenses 122 in the prior art does not occur. In addition, when the pixels of the image sensing device 100a are made smaller and smaller, when the fill factor of the lenses 122 is made larger and larger and the spacing between adjacent lenses 122 is made smaller and smaller, when the chief ray angle is made larger and larger such that the shift amount of the lenses 122 relative to the sub-pixels 112 needs to be increased, or when the sensed light 50 includes ultraviolet light or infrared light and the shift amount of the lenses 122 relative to the sub-pixels 112 needs to be increased, adjacent lenses 122 still do not have the issue of positional interfere with each other, but the shift amount of the lenses 122 may be designed at an optimal position, and the light of the target wavelength may still be correctly converged to the sub-pixels. The image sensing device 100a thus designed has lower spectral crosstalk.

In the present embodiment, a thickness T1a of a color filtering unit set 200a falls within the range of 0.4 micrometers to 2.5 micrometers. In addition, in the present embodiment, the spacer device 130 is disposed between the image sensor 110 and the color filtering unit set 200a.

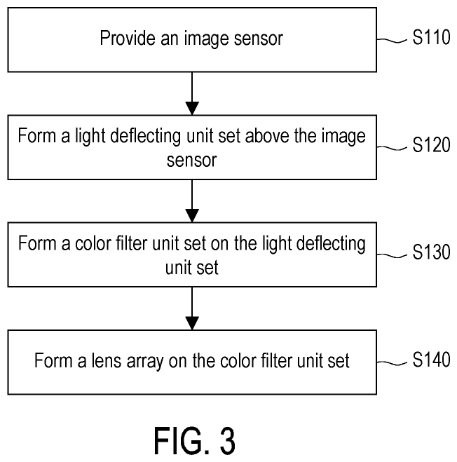

FIG. 3 is a flowchart of a manufacturing method of the image sensing device of FIG. 1B. Referring to FIG. 1B and FIG. 3, the manufacturing method of the image sensing device of the present embodiment is configured to manufacture the image sensing device 100 of FIG. 1B, and includes the following steps. First, step S110 is performed to provide the image sensor 110. The details of the image sensor 110 are as provided in the embodiments of FIG. 1A and FIG. 1B, and are not repeated herein. Next, step S120 is performed to form the light deflecting unit set 300 above the image sensor 110, for example, the spacer device 130 is disposed on the image sensor 110 first, and then the light deflecting unit set 300 is disposed on the spacer device 130. The detailed structure of the light deflecting unit set 300 and the positional relationship thereof with the image sensor 110 are as provided in the embodiments of FIG. 1A and FIG. 1B, and are not repeated herein. Then, step S130 is performed to form the color filtering unit set 200 on the light deflecting unit set 300. The detailed structure of the color filtering unit set 200 and the positional relationship thereof with other devices are as provided in the embodiments of FIG. 1A and FIG. 1B, and are not repeated herein. Then, step S140 is performed to form the lens array 120 on the color filtering unit set 200. The detailed structure of the lens array 120 and the positional relationship thereof with other devices are as provided in the embodiments of FIG. 1A and FIG. 1B, and are not repeated herein.

In the present embodiment, the method of forming the color filtering unit set 200 on the light deflecting unit set 300 is a lithography process. Moreover, in an embodiment, the method of forming the color filtering unit set 200 on the light deflecting unit set 300 includes firstly forming the second filter units 220 by a lithography process, and then forming the third filter units 230 and the first filter units 210 by a lithography process. Moreover, in the present embodiment, the method of forming the light deflecting unit set 300 above the image sensor 110 may be a lithography process, and the method of forming the lens array 120 on the color filtering unit set 200 may also be a lithography process.

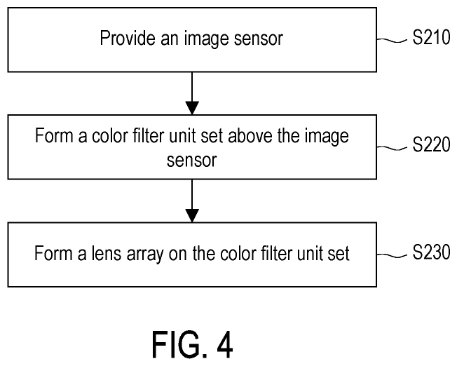

FIG. 4 is a flowchart of a manufacturing method of the image sensing device of FIG. 2. Referring to FIG. 2 and FIG. 4, the manufacturing method of the image sensing device of the present embodiment is configured to manufacture the image sensing device 100a of FIG. 2, and includes the following steps. First, step S210 is performed to provide the image sensor 110. The details of the image sensor 110 are as provided in the embodiments of FIG. 1A and FIG. 1B, and are not repeated herein. Next, step S220 is performed to form the color filtering unit set 200 above the image sensor 110, for example, the spacer device 130 is disposed on the image sensor 110 first, and then the color filter device set 200a is disposed on the spacer device 130. The detailed structure of the color filtering unit set 200a and the positional relationship thereof with the image sensor 110 are as provided in embodiment of FIG. 2, and are not repeated herein. Then, step S230 is performed to form the lens array 120 on the color filtering unit set 200a. The detailed structure of the lens array 120 and the positional relationship thereof with other devices are as provided in the embodiments of FIG. 1A and FIG. 1B, and are not repeated herein.

In the present embodiment, the method of forming the color filtering unit set 200 above the image sensor 110 is a lithography process. Moreover, in an embodiment, the method of forming the color filtering unit set 200 above the image sensor 110 includes firstly forming the second filter units 220a by a lithography process, and then forming the third filter units 230a and the first filter units 210a by a lithography process. In addition, the method of forming the lens array 120 on the color filtering unit set 200a may also be a lithography process.

Based on the above, in the image sensing device and the manufacturing method thereof of the embodiments of the invention, since light deflecting units having different refractive indices are adopted to refract light of different wavelengths, or filter units having different refractive indices are adopted to refract light of different wavelengths, the obliquely incident light of different wavelengths may be accurately converged to the corresponding sub-pixels. Therefore, the image sensing device of an embodiment of the invention or the image sensing device manufactured by the manufacturing method of the image sensing device of an embodiment of the invention has good accuracy and effect for sensing images of various colors.

What is claimed is:

1. An image sensing device, comprising:
an image sensor having a plurality of sub-pixels arranged in an array;
a color filtering unit set disposed above the image sensor and having a plurality of first filter units and a plurality of second filter units, wherein each of the first filter units and the second filter units respectively corresponds to one sub-pixel on an optical path, and a central transmission wavelength of the first filter units is greater than a central transmission wavelength of the second filter units; and
a light deflecting unit set disposed between the color filtering unit set and the image sensor and having a plurality of first light deflecting units, wherein a refractive index of the first light deflecting units is greater than a refractive index of a medium between the second filter units and a plurality of corresponding sub-pixels, and the first light deflecting units respectively correspond to the first filter units on the optical path,
wherein after passing through the first filter units and the second filter units, a light from an outside is respectively deflected by the first light deflecting units and transmitted to the plurality of corresponding sub-pixels by the medium.

2. The image sensing device of claim 1, wherein the color filtering unit set further has a plurality of third filter units, the first filter units, the second filter units, and the third filter units respectively correspond to the sub-pixels on the optical path, the central transmission wavelength of the second filter units is greater than a central transmission wavelength of the third filter units, the light deflecting unit set further has a plurality of second light deflecting units and a plurality of third light deflecting units, the refractive index of the first light deflecting units is greater than a refractive index of the second light deflecting units, the refractive index of the second light deflecting units is greater than a refractive index of the third light deflecting units, the first light deflecting units, the second light deflecting units, and the third light deflecting units correspond to the first filter units, the second filter units, and the third filter units respectively on the optical path, and after the light from the outside passes through the first filter units, the second filter units, and the third filter units, the light is respectively deflected to the corresponding sub-pixels by the first light deflecting units, the second light deflecting units, and the third light deflecting units.

3. The image sensing device of claim 2, wherein at a position deviating from a center of the image sensing device, the first filter units, the second filter units, and the third filter units are shifted toward a center of the image sensor relative to the corresponding sub-pixels.

4. The image sensing device of claim 3, wherein the first light deflecting units, the second light deflecting units, and the third light deflecting units are aligned with the corresponding sub-pixels, and the first filter units, the second filter units, and the third filter units are shifted toward the center of the image sensor relative to the corresponding first light deflecting units, second light deflecting units, and third light deflecting units.

5. The image sensing device of claim 2, further comprising a lens array comprising a plurality of lenses arranged in an array, wherein the lenses are respectively disposed on the first filter units, the second filter units, and the third filter units.

6. The image sensing device of claim 2, wherein the first filter units are red filter units, the second filter units are green filter units, and the third filter units are blue filter units.

7. The image sensing device of claim 1, wherein a ratio of a thickness of the light deflecting unit set to a thickness of the color filtering unit set is within a range of 0.8 to 38.

8. An image sensing device, comprising:
an image sensor having a plurality of sub-pixels arranged in an array; and
a color filtering unit set disposed above the image sensor and having a plurality of first filter units and a plurality of second filter units, wherein each of the first filter units and the second filter units respectively corresponds to one sub-pixel on an optical path, a central transmission wavelength of the first filter units is greater than a central transmission wavelength of the second filter units, and a refractive index of the first filter units is greater than a refractive index of the second filter units,
wherein after passing through the first filter units and the second filter units, a light from an outside is respectively deflected to the plurality of corresponding sub-pixels.

9. The image sensing device of claim 8, wherein the color filtering unit set further has a plurality of third filter units, the first filter units, the second filter units, and the third filter units respectively correspond to the sub-pixels on the optical path, the central transmission wavelength of the second filter units is greater than a central transmission wavelength of the third filter units, the refractive index of the second filter units is greater than a refractive index of the third filter units, and after passing through the first filter units, the second filter units, and the third filter units, the light from the outside is respectively deflected to the corresponding sub-pixels.

10. The image sensing device of claim 9, wherein at a position deviating from a center of the image sensing device, the first filter units, the second filter units, and the third filter units are shifted toward the center of the image sensor relative to the corresponding sub-pixels.

11. The image sensing device of claim 9, further comprising a lens array comprising a plurality of lenses arranged in an array, wherein the lenses are respectively disposed on the first filter units, the second filter units, and the third filter units.

12. The image sensing device of claim 9, wherein the first filter units are red filter units, the second filter units are green filter units, and the third filter units are blue filter units.

13. The image sensing device of claim 8, wherein a thickness of the color filtering unit set is in a range of 0.4 micrometers to 2.5 micrometers.

14. A manufacturing method of an image sensing device, comprising:
providing an image sensor, wherein the image sensor has a plurality of sub-pixels arranged in an array;
forming a light deflecting unit set above the image sensor, wherein the light deflecting unit set has a plurality of first light deflecting units respectively located above a portion of the sub-pixels; and
forming a color filtering unit set on the light deflecting unit set, wherein the color filtering unit set has a plurality of first filter units and a plurality of second filter units, each of the first filter units and the second filter units respectively corresponds to one sub-pixel on an optical path, a central transmission wavelength of the first filter units is greater than a central transmission wavelength of the second filter units, and a refractive index of the first light deflecting units is greater than a refractive index of a medium between the second filter units and a plurality of corresponding sub-pixels.

15. The manufacturing method of the image sensing device of claim 14, wherein the color filtering unit set further has a plurality of third filter units, the first filter units, the second filter units, and the third filter units respectively correspond to the sub-pixels on the optical path, the central transmission wavelength of the second filter units is greater than a central transmission wavelength of the third filter units, the light deflecting unit set further has a plurality of second light deflecting units and a plurality of third light deflecting units, the refractive index of the first light deflecting units is greater than a refractive index of the second light deflecting units, the refractive index of the second light deflecting units is greater than a refractive index of the third light deflecting units, and the first light deflecting units, the second light deflecting units, and the third light deflecting units correspond to the first filter units, the second filter units, and the third filter units respectively on the optical path.

16. The manufacturing method of the image sensing device of claim 15, wherein a method of forming the color filtering unit set above the light deflecting unit set is a lithography process.

17. The manufacturing method of the image sensing device of claim 16, wherein a method of forming the color filtering unit set on the light deflecting unit set comprises first forming the second filter units by the lithography process, and then forming the third filter units and the first filter units by the lithography process.

18. The manufacturing method of the image sensing device of claim 14, wherein a method of forming the light deflecting unit set above the image sensor is a lithography process.

19. The manufacturing method of the image sensing device of claim 15, wherein at a position deviating from a center of the image sensor, the first filter units, the second filter units, and the third filter units are shifted toward the center of the image sensor relative to the corresponding sub-pixels.

20. The manufacturing method of the image sensing device of claim 15, further comprising forming a lens array on the color filtering unit set, wherein the lens array comprises a plurality of lenses arranged in an array, wherein the lenses are respectively disposed on the first filter units, the second filter units, and the third filter units.

21. The manufacturing method of the image sensing device of claim 15, wherein the first filter units are red filter units, the second filter units are green filter units, and the third filter units are blue filter units.

22. The manufacturing method of the image sensing device of claim 14, wherein a ratio of a thickness of the light deflecting unit set to a thickness of the color filtering unit set is within a range of 0.8 to 38.

23. A manufacturing method of an image sensing device, comprising:
providing an image sensor, wherein the image sensor has a plurality of sub-pixels arranged in an array; and
forming a color filtering unit set above the image sensor, wherein the color filtering unit set has a plurality of first filter units and a plurality of second filter units, each of the first filter units and the second filter units respectively corresponds to one sub-pixel on an optical path, a central transmission wavelength of the first filter units is greater than a central transmission wavelength of the second filter units, and a refractive index of the first filter units is greater than a refractive index of the second filter units.

24. The manufacturing method of the image sensing device of claim 23, wherein the color filtering unit set further has a plurality of third filter units, the first filter units, the second filter units, and the third filter units respectively correspond to the sub-pixels on the optical path, the central transmission wavelength of the second filter units is greater than a central transmission wavelength of the third filter units, and the refractive index of the second filter units is greater than a refractive index of the third filter units.

25. The manufacturing method of the image sensing device of claim 24, wherein a method of forming the color filtering unit set above the image sensor is a lithography process.

26. The manufacturing method of the image sensing device of claim 25, wherein a method of forming the color filtering unit set on the image sensor comprises first forming the second filter units by the lithography process, and then forming the third filter units and the first filter units by the lithography process.

27. The manufacturing method of the image sensing device of claim 24, wherein at a position deviating from a center of the image sensor, the first filter units, the second filter units, and the third filter units are shifted toward the center of the image sensor relative to the corresponding sub-pixels.

28. The manufacturing method of the image sensing device of claim 24, further comprising forming a lens array on the color filtering unit set, wherein the lens array comprises a plurality of lenses arranged in an array, wherein the lenses are respectively disposed on the first filter units, the second filter units, and the third filter units.

29. The manufacturing method of the image sensing device of claim 24, wherein the first filter units are red filter units, the second filter units are green filter units, and the third filter units are blue filter units.

30. The manufacturing method of the image sensing device of claim 23, wherein a thickness of the color filtering unit set is in a range of 0.4 micrometers to 2.5 micrometers.
